(19) United States
(12) Patent Application Publication
(10) Pub. No.: US 2025/0338690 A1
(43) Pub. Date: Oct. 30, 2025

(54) DISPLAY DEVICE AND METHOD OF MANUFACTURING THE SAME

(71) Applicant: Samsung Display Co., Ltd., Yongin-si (KR)

(72) Inventors: JAEHAK LEE, Yongin-si (KR); SI JOON SONG, Yongin-si (KR)

(21) Appl. No.: 19/054,636

(22) Filed: Feb. 14, 2025

(30) Foreign Application Priority Data
Apr. 30, 2024 (KR) 10-2024-0057614

(51) Int. Cl. H10H 29/49; H10H 29/01; H10H 29/85; H10K 59/12; H10K 59/131; H10K 71/60

(52) U.S. Cl. CPC H10H 29/49; H10H 29/012; H10H 29/0364; H10H 29/8508; H10K 59/1201; H10K 59/131; H10K 71/60

(57) ABSTRACT

A manufacturing method of a display device includes providing a plurality of pad electrodes exposed through an opening defined through a base layer and arranged in a first direction and a plurality of bump electrodes on the pad electrodes overlapping the pad electrodes, respectively, when viewed in a plane, placing a preliminary metal layer having a substantially non-uniform thickness in a second direction intersecting the first direction on the pad electrodes and the bump electrodes, placing a mold on the preliminary metal layer to form a metal layer with a flat upper surface, and irradiating a laser to a first portion of the metal layer, the first portion of the metal layer not overlapping the pad electrodes and the bump electrodes, to form a plurality of metal patterns. The pad electrodes are electrically connected to the bump electrodes by (via) the metal patterns.

### CROSS-REFERENCE TO RELATED APPLICATION(S)

The present application claims priority to and the benefit of Korean Patent Application No. 10-2024-0057614, filed on Apr. 30, 2024, in the Korean Intellectual Property Office, the entire disclosure of which is incorporated herein by reference.

### BACKGROUND

### 1. Field

Embodiments of the present disclosure described herein are related to a display device and a method of manufacturing the display device. More particularly, Embodiments of the present disclosure described herein are related to a display device with improved reliability and a method of manufacturing the display device.

### 2. Description of Related Art

Electronic devices, including smartphones, tablet computers, notebook computers, car navigation units, and/or smart televisions, are continually being developed. These electronic devices incorporate display devices to convey (provide) information.

Various types (kinds) of display devices are being developed to enhance user experience (UX) and the user interface (UI). For instance, research is being conducted to provide display devices with a wide display area and a narrow non-display area.

The information disclosed in this Background section is intended to enhance understanding of the background of the disclosure and therefore it may contain information that does not constitute prior art.

### SUMMARY

Aspects according to one or more embodiments of the present disclosure are directed toward a display device manufactured by a simplified manufacturing method with reduced damages on a substrate.

Aspects according to one or more embodiments of the present disclosure are directed toward a method of manufacturing the display device.

Additional aspects will be set forth in part in the description which follows and, in part, will be apparent from the description, or may be learned by practice of the presented embodiments of the disclosure.

One or more embodiments of the present disclosure include a display device including a display panel configured to display an image, a circuit board coupled with the display panel, and a plurality of metal patterns electrically connecting the display panel and the circuit board and including a flat upper surface. The display panel includes a base layer including a pad electrode exposed to an outside through an opening and a circuit layer arranged on the base layer and including at least one signal line electrically connected to the pad electrode. The upper surface is substantially parallel to an upper surface of the pad electrode.

In one or more embodiments, each of the metal patterns includes a first sub-metal pattern and a second sub-metal pattern being extended from the first sub-metal pattern, and the first sub-metal pattern has a thickness greater than a thickness of the second sub-metal pattern.

In one or more embodiments, the first sub-metal pattern includes a first upper surface substantially parallel to a second upper surface of the second sub-metal pattern.

In one or more embodiments, the circuit board includes a base film and a bump electrode arranged between the base film and the base layer, and the bump electrode is electrically connected to the pad electrode by the metal patterns.

One or more embodiments of the present disclosure include a method of manufacturing a display device. The method includes providing a plurality of pad electrodes exposed through an opening defined through a base layer and arranged in a first direction and providing a plurality of bump electrodes arranged on the pad electrodes overlapping the pad electrodes, respectively, if (e.g., when) viewed in a plane, placing a preliminary metal layer having a substantially non-uniform thickness in a second direction intersecting the first direction on the pad electrodes and the bump electrodes, placing a mold on the preliminary metal layer to form a metal layer with a flat upper surface, and irradiating a laser to a first portion of the metal layer, the first portion of the metal layer not overlapping the pad electrodes and the bump electrodes, to form a plurality of metal patterns. The pad electrodes are electrically connected to the bump electrodes by the metal patterns.

In one or more embodiments, the forming of the metal layer includes pressing the preliminary metal layer using the mold and curing the preliminary metal layer.

In one or more embodiments, the curing of the preliminary metal layer includes irradiating a light to the mold.

In one or more embodiments, the mold is configured to transmit a light having a wavelength equal to or greater than about 350 nm and equal to or smaller than about 450 nm.

In one or more embodiments, the mold includes a depressed portion defined therein, and the depressed portion has a quadrangular shape in a cross-section if (e.g., when) viewed in the first direction.

In one or more embodiments, the metal layer and the depressed portion are extended in the first direction.

In one or more embodiments, a shape in the cross-section of the first portion if (e.g., when) viewed in the first direction is equal to a shape in the cross-section of the depressed portion if (e.g., when) viewed in the first direction, and the first portion has a substantially uniform thickness in the second direction.

In one or more embodiments, the depressed portion is provided in plural, and the depressed portions are arranged in the first direction.

In one or more embodiments, the first portion has a thickness smaller than a thickness of a second portion of the metal layer, the second portion of the metal layer overlapping the pad electrodes and the bump electrodes.

In one or more embodiments, the second portion of the metal layer, which overlaps the pad electrodes and the bump electrodes, overlaps the depressed portions.

In one or more embodiments, each of the metal patterns includes a first sub-metal pattern and a second sub-metal pattern being extended from the first sub-metal pattern, and the first sub-metal pattern and the second sub-metal pattern have different thicknesses from each other.

In one or more embodiments, the second sub-metal pattern corresponds to a portion of the first portion, which remains after the other portion of the first portion is removed by the laser, the first sub-metal pattern corresponds to the second portion, and the first sub-metal pattern has a thickness greater than a thickness of the second sub-metal pattern.

In one or more embodiments, the first sub-metal pattern includes a first upper surface that is substantially parallel to a second upper surface of the second sub-metal pattern.

In one or more embodiments, the second sub-metal pattern has a substantially uniform thickness in the second direction.

In one or more embodiments, the method further includes removing the mold before the forming of the metal patterns.

In one or more embodiments, the method further includes placing an adhesive layer on the pad electrodes before the providing of the bump electrodes.

According to the above, the manufacturing method of the display device includes the pressing of the metal layer, which has the substantially non-uniform thickness, using the mold, and thus, the metal layer with the flat upper surface is formed. Thus, a substrate arranged under the metal layer is not damaged if (e.g., when) the laser is being irradiated onto the metal layer, and the reliability of the display device is improved.

### BRIEF DESCRIPTION OF THE DRAWINGS

The above and other advantages of the present disclosure will become readily apparent by reference to the following detailed description if (e.g., when) considered in conjunction with the accompanying drawings wherein:

FIG. 1 is a perspective view of an electronic device according to one or more embodiments of the present disclosure;

FIG. 2 is an exploded perspective view of an electronic device according to one or more embodiments of the present disclosure;

FIG. 3 is a cross-sectional view of a display device taken along a line I-I′ of FIG. 2;

FIG. 4 is a cross-sectional view of a display module according to one or more embodiments of the present disclosure;

FIG. 5 is a plan view of a display panel according to one or more embodiments of the present disclosure;

FIG. 6 is a cross-sectional view of a display module according to one or more embodiments of the present disclosure;

FIG. 7 is a plan view of a display panel according to one or more embodiments of the present disclosure;

FIG. 8 is an enlarged plan view of a portion of a display device according to one or more embodiments of the present disclosure;

FIG. 9A is a cross-sectional view of a portion of a display device taken along a line II-II′ of FIG. 8;

FIG. 9B is a cross-sectional view of a portion of a display device taken along a line III-III′ of FIG. 8;

FIG. 10A is a cross-sectional view of a portion of a display device according to one or more embodiments of the present disclosure;

FIG. 10B is an enlarged view of an area AA′ of FIG. 10A;

FIG. 11 is a cross-sectional view of a portion of a display device according to one or more embodiments of the present disclosure;

FIGS. 12-17 are views illustrating processes of a manufacturing method of a display device according to one or more embodiments of the present disclosure; and

FIGS. 18A-18C are views illustrating processes of a manufacturing method of a display device according to one or more embodiments of the present disclosure.

### DETAILED DESCRIPTION

The present disclosure may be variously modified and realized in many different forms, and thus one or more embodiments will be illustrated in the drawings and described in more detail hereinbelow. However, the present disclosure should not be limited to the specific disclosed forms, and be construed to include all modifications, equivalents, or replacements included in the spirit and scope of the present disclosure.

In the present disclosure, it will be understood that if (e.g., when) an element (or area, layer, or portion) is referred to as being “on”, “connected to” or “coupled to” another element or layer, it can be directly on, connected or coupled to the other element or layer or intervening elements or layers may be present.

Like numerals refer to like elements throughout, and duplicative descriptions thereof may not be provided. In the drawings, the thickness, ratio, and dimension of components are exaggerated for effective description of the technical content (e.g., amount).

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” may include any and all combinations of one or more of the associated listed items.

It will be understood that, although the terms first, second, and/or the like may be used herein to describe one or more suitable elements, these elements should not be limited by these terms. These terms are only used to distinguish one element from another element. Thus, a first element discussed could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and/or the like, may be used herein for ease of description to describe one element or feature's relationship to another elements or features as shown in the drawings.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” and/or “including”, if (e.g., when) used in this specification, specify the presence of stated features, integers, steps, operations, elements, and/or components, but do not preclude the presence or addition of one or more other features, integers, steps, operations, elements, components, and/or groups thereof.

Hereinafter, embodiments of the present disclosure will be described in more detail with reference to accompanying drawings.

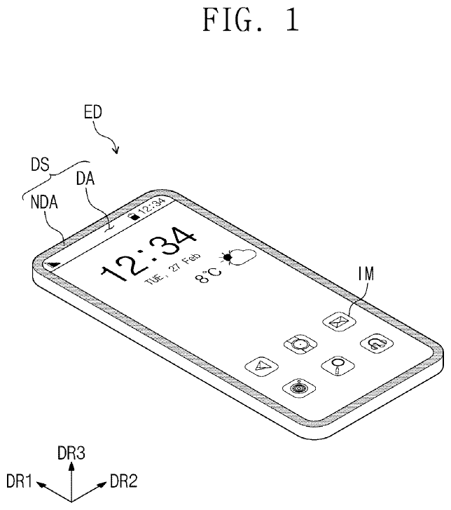

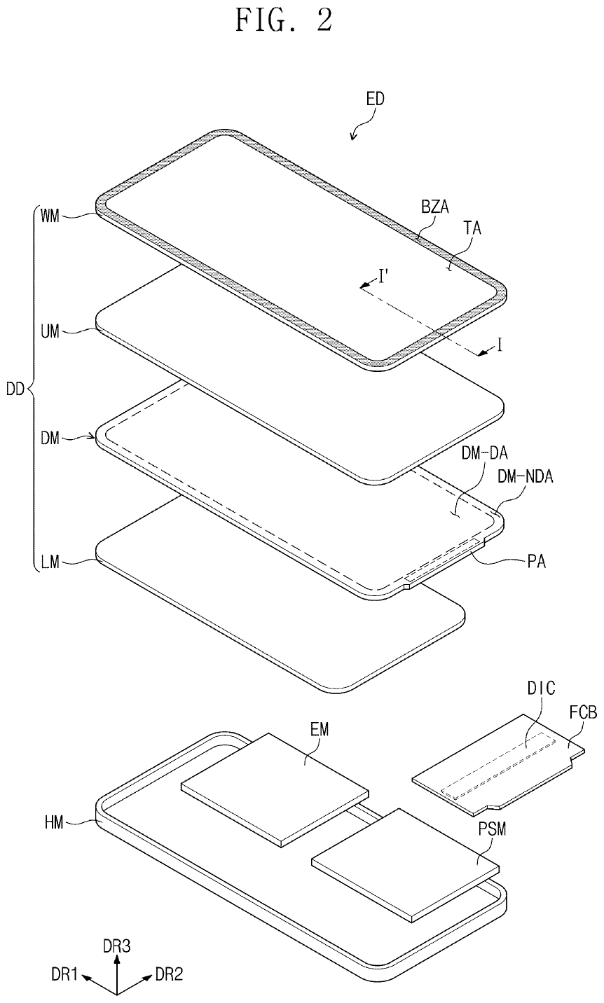

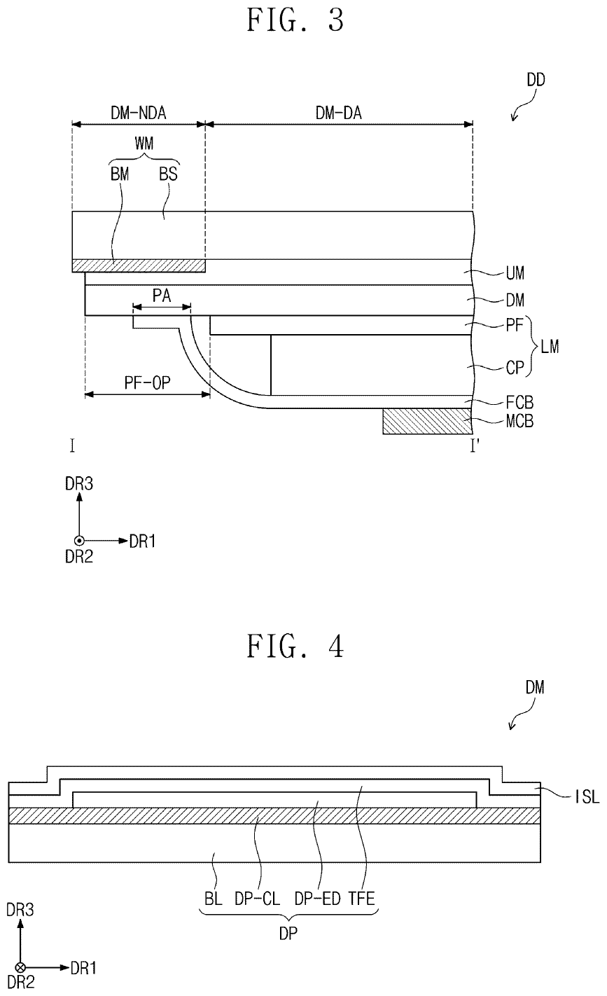

FIG. 1 is a perspective view of an electronic device ED according to one or more embodiments of the present disclosure. FIG. 2 is an exploded perspective view of the electronic device ED according to one or more embodiments of the present disclosure. FIG. 3 is a cross-sectional view of a display device DD taken along a line I-I′ of FIG. 2.

Referring to FIG. 1, the electronic device ED may include a display surface DS defined by a first direction DR1 and a second direction DR2 intersecting the first direction DR1. The electronic device ED may provide an image IM to a user through the display surface DS.

The display surface DS may include a display area DA and a non-display area NDA around the display area DA. The display area DA may display the image IM, and the non-display area NDA may not display the image IM. The non-display area NDA may be around (e.g., surround) the display area DA, however, it should not be limited thereto or thereby, and the shape of the display area DA and the shape of the non-display area NDA may be changed.

Hereinafter, a direction substantially normal (e.g., perpendicular) to the plane defined by the first direction DR1 and the second direction DR2 may be referred to as a third direction DR3. Front and rear surfaces of each member of the electronic device ED may be distinguished from each other with respect to the third direction DR3. In the present disclosure, the expression “if (e.g., when) viewed in a plane” may refer to a state of being viewed in the third direction DR3. Also, in the content of the present disclosure and unless define otherwise, a “plan view” refers to a view of the electronic device ED as seen from above, looking down along the third direction DR3. In this view, the front and rear surfaces of each component of the electronic device ED can be distinguished based on their orientation relative to the third direction DR3. Also, a “cross-sectional view” refers to a view of the electronic device ED as seen along a plane that cuts through the device, typically perpendicular to one of its main axes. This view reveals the internal structure and components of the device along the line of the cut. For example, FIG. 3 shows a cross-sectional view of the display device DD taken along the line I-I′ of FIG. 2, providing insight into the internal configuration of the display device.

The electronic device ED may be a foldable electronic device folded with respect to a folding axis. The folding axis may be substantially parallel to the first direction DR1 or the second direction DR2, and a folding area may be defined in a portion of the display area DA. The electronic device ED may be inwardly folded (inner-folding) to allow one portion of the display area DA to face the other portion of the display area DA or may be outwardly folded (outer-folding) to allow the one portion and the other portion of the display area DA to face opposite directions to each other.

Referring to FIG. 2, the electronic device ED may include the display device DD, an electronic module EM, a power source module PSM, and a housing HM. The electronic device ED is schematically shown in FIG. 2, and the electronic device ED may further include a mechanical structure (e.g., a hinge) to control an operation, for example, a folding or rolling operation, of the display device DD.

The display device DD may be configured to generate the image IM and may be configured to sense an external input. The display device DD may include a window WM, an upper member UM, a display module DM, a lower member LM, a circuit board (or a flexible circuit board) FCB, and a driving chip DIC. The upper member UM may include components arranged above the display module DM, and the lower member LM may include components arranged below the display module DM.

The window WM may provide a front surface of the electronic device ED. The window WM may include a transmission area TA and a bezel area BZA. The display area DA and the non-display area NDA of the display surface DS shown in FIG. 1 may be defined by the transmission area TA and the bezel area BZA. The transmission area TA may be an area through which the image passes, and the bezel area BZA may be an area that covers structures/members arranged under the window WM.

The display module DM may include a display area DM-DA and a non-display area DM-NDA, which respectively correspond to the display area DA and the non-display area NDA shown in FIG. 1. In the present disclosure, the expression “An area/portion corresponds to another area/portion” refers to that “An area/portion overlaps another area/portion”, however, they should not be limited to having the same size as each other. For example, the area/portion corresponding to another area/portion may have the same size as each other or may have different sizes from each other. For example, the area/portion corresponding to another area/portion may have the same size or different sizes.

A pad area PA may be defined at one side of the non-display area DM-NDA. The pad area PA may be electrically bonded or connected to the circuit board FCB described in more detail later. In the present embodiment, the pad area PA may be defined in a rear surface of the display module DM.

The display module DM may have a substantially quadrangular shape. The expression “a substantially quadrangular shape” used herein may refer to not only the mathematical concept of a rectangular shape, but also shapes that are similar to rectangles and perceived by the user as rectangles. For instance, the substantially quadrangular shape may include a quadrangular shape with a rounded corner. In addition, an edge of the display module DM having the substantially rectangular shape should not be limited to a straight line, and the edge may have a curved area.

The upper member UM may include a protective film or an optical film. The optical film may include a polarizer or a retarder to reduce a reflection of an external light. The lower member LM may include a protective film protecting the display module DM, a support member supporting the display module DM, and a digitizer. The upper member UM and the lower member LM will be described in more detail later.

The circuit board FCB may be arranged under the display module DM. The circuit board FCB may be bonded to a rear surface of the display module DM. The circuit board FCB may electrically connect the display module DM to a main circuit board MCB (refer to FIG. 3). In other words, the display module DM may be electrically connected to the main circuit board MCB by (via) the circuit board FCB. The circuit board FCB may include at least one insulating layer and at least one conductive layer. The conductive layer may include a plurality of signal lines.

The driving chip DIC may be mounted on the circuit board FCB. The driving chip DIC may include a driving circuit, e.g., a data driving circuit, to drive pixels of the display module DM. FIG. 2 shows a structure in which the driving chip DIC is mounted on the circuit board FCB, however, the present disclosure should not be limited thereto or thereby. As an example, the driving chip DIC may be mounted on the display module DM or the main circuit board.

The electronic module EM may include a control module, a wireless communication module, an image input module, an audio input module, an audio output module, a memory, and an external interface module. The electronic module EM may include the main circuit board, and the modules may be mounted on the main circuit board or may be electrically connected to the main circuit board via a flexible circuit board. The electronic module EM may be electrically connected to the power source module PSM.

In one or more embodiments, the electronic device ED may further include an electro-optical module. The electro-optical module may be an electronic component that is configured to output or to receive an optical signal. The electro-optical module may include a camera module and/or a proximity sensor. The camera module may take a picture of an external object via an area of the display module DM.

The housing HM shown in FIG. 2 may be coupled to the display device DD, particularly, the window WM to accommodate the above-mentioned modules. The housing HM is shown as having an integral shape, however, it should not be limited thereto or thereby. The housing HM may include a plurality of portions, for instance, a side surface edge portion and a bottom portion, coupled to each other.

Referring to FIG. 3, the window WM may include a base substrate BS and a bezel pattern BM arranged on a lower surface of the base substrate BS. The base substrate BS may include a synthetic resin film or a glass substrate. The base substrate BS may have a multi-layer structure. The base substrate BS may include a thin glass substrate, a protective film arranged on the thin glass substrate, and an adhesive layer that attaches the thin glass substrate and the protective film.

The bezel pattern BM may be a colored light blocking layer and may be formed by a coating process. The bezel pattern BM may include a base material and a pigment or dye mixed with the base material. The bezel pattern BM may overlap the non-display area NDA shown in FIG. 1 and the bezel area BZA shown in FIG. 2. The bezel pattern BM may be arranged on the lower surface of the base substrate BS. When the base substrate BS has the multi-layer structure, the bezel pattern BM may be arranged at an interface defined between plural layers. For instance, the bezel pattern BM may be arranged between the thin glass substrate and the protective film. In one or more embodiments, the window WM may further include at least one of a hard coating layer, an anti-fingerprint layer, or an anti-reflective layer arranged on an upper surface of the base substrate BS.

The upper member UM may include an upper film. The upper film may include or be a synthetic resin film. The synthetic resin film may include or be composed of polyimide, polycarbonate, polyamide, triacetylcellulose, polymethylmethacrylate, and/or polyethylene terephthalate.

The upper film may be configured to absorb an external impact applied to a front surface of the display device DD. According to one or more embodiments, the display module DM may include a color filter as an anti-reflective member to replace a polarizing film, and in this case, an impact resistance of the display device DD with respect to external impacts applied to the front surface thereof may be reduced. The upper film may compensate for the reduction of the impact resistance with respect to the external impacts, which is caused by applying the color filter to the display module DM.

The upper member UM may overlap the bezel area BZA (refer to FIG. 2) and the transmission area TA (refer to FIG. 2). The upper member UM may overlap only a portion of the bezel area BZA. A portion of the bezel pattern BM may be exposed without being covered by the upper member UM. According to one or more embodiments, the upper member UM may not be provided. According to one or more embodiments, the upper member UM may be replaced with the optical film including the polarizer and the retarder.

In one or more embodiments, an adhesive layer attaching the upper member UM and the window WM may be arranged between the upper member UM and the window WM. The adhesive layer may be a pressure sensitive adhesive (PSA) film or an optically clear adhesive (OCA).

The display module DM may be arranged under the upper member UM. The display module DM may overlap the bezel area BZA and the transmission area TA. The display module DM may completely overlap the upper member UM in the bezel area BZA. A side surface of the display module DM may be aligned with a side surface of the upper member UM, and a corner of the display module DM may be aligned with a corner of the upper member UM if (e.g., when) viewed in the plane (e.g., in a plan view).

In the bezel area BZA, the pad area PA of the display module DM may overlap the upper member UM. A portion of the display module DM, which corresponds to the pad area PA, may be coupled with a lower surface of the upper member UM by an adhesive layer. As the pad area PA overlaps the upper member UM and the portion of the display module DM overlapping the pad area PA is coupled with the upper member UM, the upper member UM may sufficiently support the pad area PA if (e.g., when) the circuit board FCB is bonded to the pad area PA.

The lower member LM may include a lower film PF and a cover panel CP. The lower member LM may further include a support plate and a digitizer.

The lower film PF may expose the pad area PA of the display module DM. The lower film PF may have a size smaller than that of the display module DM. For instance, the lower film PF may overlap only the display area DM-DA. The lower film PF may be provided with an opening area PF-OP defined therein to correspond to the non-display area DM-NDA. In one or more embodiments, the lower film PF may have substantially the same size as the display module DM. In this case, the lower film PF may be provided with an opening area PF-OP defined therein to correspond to the pad area PA. The pad area PA may be exposed through the opening area PF-OP.

The cover panel CP may be arranged under the lower film PF. The cover panel CP may increase a resistance against a compressive force caused by external pressure force. Accordingly, the cover panel CP may prevent or reduce the display module DM from being deformed. The cover panel CP may include a flexible plastic material, such as polyimide or polyethylene terephthalate. In addition, the cover panel CP may be a colored film with low light transmittance. The cover panel CP may be configured to absorb a light incident thereto from the outside. As an example, the cover panel CP may be a black synthetic resin film. When looking at the display device DD from above the window WM, components arranged under the cover panel CP may not be viewed by the user.

In one or more embodiments, the support plate may be further arranged under the cover panel CP. The support plate may include a high-strength metal material. The support plate may include a reinforced fiber composite material. The support plate may include a reinforced fiber arranged in a matrix portion. The reinforced fiber may be a carbon fiber or a glass fiber. The matrix portion may include a polymer resin. The matrix portion may include a thermoplastic resin. As an example, the matrix portion may include a polyamide-based resin or a polypropylene-based resin. For example, the reinforced fiber composite material may be a carbon fiber reinforced plastic (CFRP) and/or a glass fiber reinforced plastic (GFRP).

The main circuit board MCB may be arranged on a lower surface of the circuit board FCB. The circuit board FCB may include an insulating film and conductive lines mounted on the insulating film. The main circuit board MCB may include signal lines and electronic elements. The electronic elements may be connected to the signal lines and may be electrically connected to the display module DM. The electronic elements may generate one or more suitable electrical signals, e.g., a signal to generate images or a signal to sense the external input, or may process the sensed signal. In one or more embodiments, the main circuit board MCB may be provided to correspond to each of the electrical signals to be generated and processed, and three or more main circuit boards MCB may be provided. However, it should not be particularly limited thereto.

In one or more embodiments, the main circuit board MCB may include the driving chip DIC (refer to FIG. 2) mounted therein.

Referring to FIGS. 2 and 3, the circuit board FCB may be coupled with the rear surface of the display module DM (a rear-surface bonding). Because the non-display area DM-NDA of the display module DM is not bent, defects occurring if (e.g., when) the display module DM is bent may be prevented or reduced in the non-display area DM-NDA. In addition, a size of the bezel area BZA of the window WM, which is desired or required to cover the non-display area DM-NDA of the display module DM, may be reduced.

FIG. 4 is a cross-sectional view of the display module DM according to one or more embodiments of the present disclosure.

Referring to FIG. 4, the display module DM may include the display panel DP and an input sensing layer ISL. The display panel DP may include a base layer BL, a circuit layer DP-CL, a display element layer DP-ED, and an encapsulation layer TFE.

The circuit layer DP-CL may be arranged on an upper surface of the base layer BL. The base layer BL may be a flexible substrate that is bendable, foldable, and/or rollable. The base layer BL may be a glass substrate, a metal substrate, and/or a polymer substrate, however, it should not be limited thereto or thereby. According to one or more embodiments, the base layer BL may be an inorganic layer, an organic layer, or a composite material layer. The base layer BL may have substantially the same shape as the display panel DP.

The base layer BL may have a multi-layer structure. For instance, the base layer BL may include a first synthetic resin layer, a second synthetic resin layer, and inorganic layers arranged between the first synthetic resin layer and the second synthetic resin layer. Each of the first and second synthetic resin layers may include a polyimide-based resin, however, it should not be particularly limited.

The circuit layer DP-CL may be arranged on the base layer BL. The circuit layer DP-CL may include a plurality of insulating layers, a plurality of semiconductor patterns, a plurality of conductive patterns, and a plurality of signal lines. The circuit layer DP-CL may include a pixel driving circuit. Hereinafter, unless otherwise specified, the expression “Components A and B are arranged on the same layer” refers to that components A and B are formed through substantially the same process and contain substantially the same material or have the same stack structure. The conductive patterns or the semiconductor patterns arranged on the same layer may be interpreted as described above.

The display element layer DP-ED may be arranged on the circuit layer DP-CL. The display element layer DP-ED may include a light emitting element. For example, the light emitting element may include or be an organic light emitting material, an inorganic light emitting material, an organic-inorganic light emitting material, a quantum dot, a quantum rod, a micro-LED, or a nano-LED.

The encapsulation layer TFE may be arranged on the display element layer DP-ED. The encapsulation layer TFE may protect the display element layer DP-ED, i.e., the light emitting element, from moisture, oxygen, and a foreign substance such as dust particles. The encapsulation layer TFE may include at least one encapsulation inorganic layer. The encapsulation layer TFE may include a stack structure in which a first encapsulation inorganic layer, an encapsulation organic layer, and a second encapsulation inorganic layer are sequentially stacked.

The input sensing layer ISL may be arranged directly on the display panel DP. The input sensing layer ISL may sense a user's input by an electromagnetic induction method or a capacitive method. The display panel DP and the input sensing layer ISL may be formed through successive processes. The expression “being directly arranged on” as used herein may refer to that no intervening elements are arranged between the input sensing layer ISL and the display panel DP. For example, a separate adhesive layer may not be arranged between the input sensing layer ISL and the display panel DP.

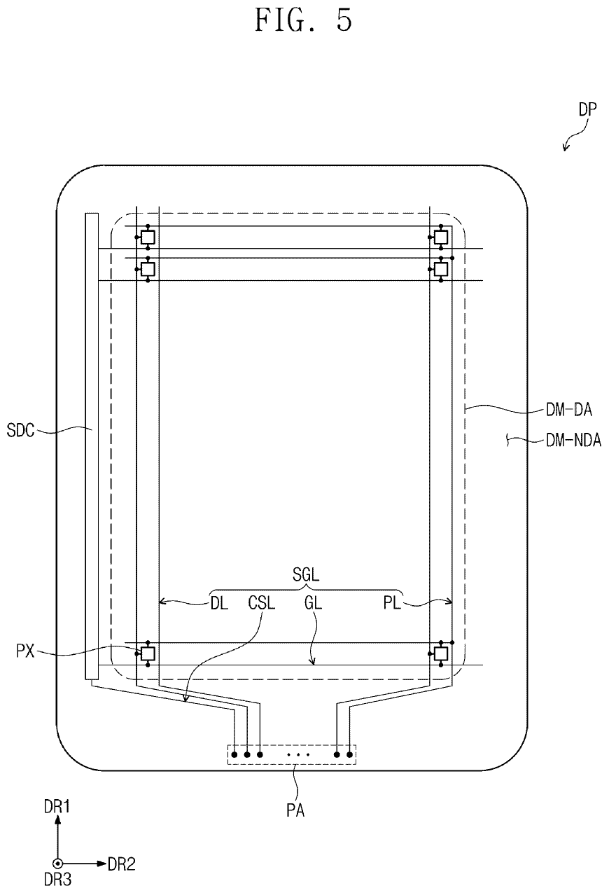

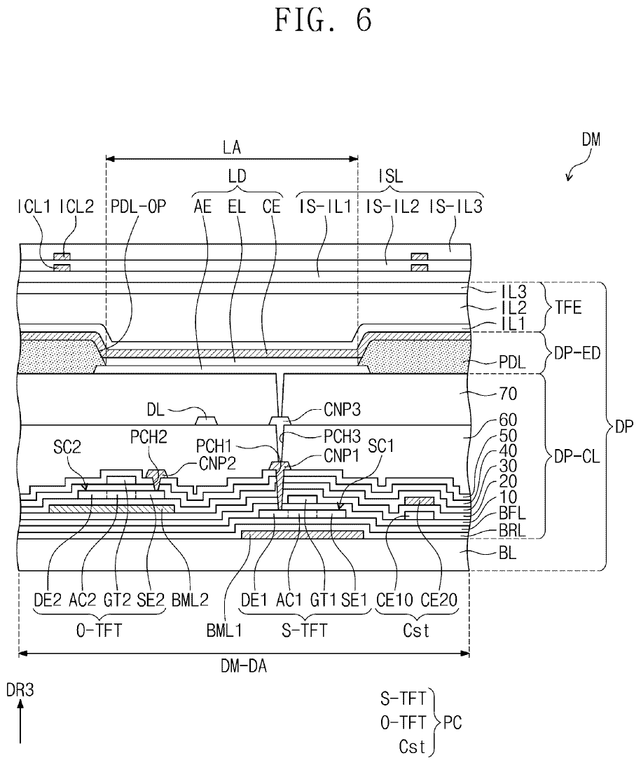

FIG. 5 is a plan view of the display panel DP according to one or more embodiments of the present disclosure. FIG. 6 is a cross-sectional view of the display module DM according to one or more embodiments of the present disclosure.

Referring to FIG. 5, the display panel DP may include a scan driving circuit SDC, a plurality of signal lines SGL, and a plurality of pixels PX. The pixels PX may be arranged in the display area DM-DA. Each of the pixels PX may include the light emitting element and the pixel driving circuit connected to the light emitting element. The scan driving circuit SDC, the signal lines SGL, and the pixel driving circuit may be included in the circuit layer DP-CL shown in FIG. 4.

The scan driving circuit SDC may include a gate driving circuit. The gate driving circuit may generate a plurality of scan signals and may sequentially output the scan signals to a plurality of scan lines GL described in more detail later. The scan driving circuit SDC may further include a light emission driving circuit distinguished from the gate driving circuit. The light emission driving circuit may further output scan signals to another group of scan lines.

The scan driving circuit SDC may include a plurality of thin film transistors formed through substantially the same processes, e.g., a low temperature polycrystalline silicon (LTPS) process or a low temperature polycrystalline oxide (LTPO) process, as the pixel driving circuit.

The signal lines SGL may include the scan lines GL, data lines DL, a power line PL, and a control signal line CSL. Each of the scan lines GL may be connected to a corresponding pixel PX among the pixels PX, and each of the data lines DL may be connected to a corresponding pixel PX among the pixels PX. The power line PL may be connected to the pixels PX. The data lines DL may provide data signals to the pixels PX. The control signal line CSL may provide control signals to the scan driving circuit SDC.

The power line PL may be provided in plural. As an example, the power line PL may include a first power line receiving a first power supply voltage and a second power line receiving a second power supply voltage having a level higher than the first power supply voltage. The first power supply voltage may be provided to the pixel PX via the first power line, and the second power supply voltage may be provided to the pixel PX via the second power line. One control signal line CSL is shown in FIG. 5 as a representative example, however, the control signal line CSL may be provided in plural.

The scan lines GL, the data lines DL, and the power line PL may overlap the display area DM-DA and the non-display area DM-NDA, and the control signal line CSL may overlap the non-display area DM-NDA. Ends of the signal lines SGL may be aligned in one side of the non-display area DM-NDA. Each of the signal lines SGL may have an integral shape but may include a plurality of portions arranged on different layers (e.g., the signal line is designed as one cohesive entity, even though it may be composed of multiple segments or portions arranged on different layers). The portions arranged on different layers from each other and distinguished from each other by an insulating layer may be connected to each other via a contact hole defined through the insulating layer. For instance, each of the data lines DL may include a first portion arranged in the display area DM-DA and a second portion arranged in the non-display area DM-NDA and arranged on a different layer from the first portion. The first portion and the second portion may include different materials from each other and may have different stack structures from each other.

The signal lines SGL may be electrically connected to the main circuit board MCB shown in FIG. 3 via the pad area PA.

FIG. 6 shows a cross-section of the display module DM corresponding to the pixel PX of FIG. 5.

The pixel driving circuit PC that drives the light emitting element LD may include a plurality of pixel driving elements. The pixel driving circuit PC may include a plurality of transistors S-TFT and O-TFT and a capacitor Cst. The transistors may include a silicon transistor S-TFT and an oxide transistor O-TFT. FIG. 6 shows the silicon transistor S-TFT and the oxide transistor O-TFT as a representative example of the transistors. The pixel driving circuit PC of FIG. 6 is merely an example, and components of the pixel driving circuit PC should not be limited thereto or thereby. The pixel driving circuit PC may include only one type (kind) of transistor between the silicon transistor S-TFT and the oxide transistor O-TFT.

Referring to FIG. 6, the base layer BL has a single-layer structure. The base layer BL may include a synthetic resin such as polyimide. The base layer BL may be formed by coating a synthetic resin layer on a work substrate (or a carrier substrate). When the display module DM is completed through subsequent processes, the work substrate may be removed.

Referring to FIG. 6, a first shielding electrode (or a shielding electrode) BML1 may be arranged on the base layer BL. The first shielding electrode BML1 may receive a bias voltage. The first shielding electrode BML1 may receive the first power supply voltage. The first shielding electrode BML1 may prevent or reduce an electric potential caused by a polarization phenomenon from exerting influence on the silicon transistor S-TFT. The first shielding electrode BML1 may prevent or reduce an external light from reaching the silicon transistor S-TFT. According to one or more embodiments, the first shielding electrode BML1 may be a floating electrode isolated from other electrodes or lines. The first shielding electrode BML1 may be arranged to correspond to the silicon transistor S-TFT. The first shielding electrode BML1 may include a metal material, e.g., molybdenum.

A barrier layer BRL may be arranged on the base layer BL and the first shielding electrode BML1. The barrier layer BRL may prevent or reduce a foreign substance from entering thereinto from the outside. The barrier layer BRL may include at least one inorganic layer. The barrier layer BRL may include a silicon oxide layer and a silicon nitride layer. Each of the silicon oxide layer and the silicon nitride layer may be provided in plural, and the silicon oxide layers may be alternately stacked with the silicon nitride layers.

A buffer layer BFL may be arranged on the barrier layer BRL. The buffer layer BFL may prevent or reduce metal atoms or impurities from being diffused to a first semiconductor pattern SC1 arranged thereon from the base layer BL. The buffer layer BFL may include at least one inorganic layer. The buffer layer BFL may include a silicon oxide layer and a silicon nitride layer.

The first semiconductor pattern SC1 may be arranged on the buffer layer BFL. The first semiconductor pattern SC1 may include a silicon semiconductor. As an example, the silicon semiconductor may include amorphous silicon or polycrystalline silicon. For example, the first semiconductor pattern SC1 may include low temperature polycrystalline silicon.

The first semiconductor pattern SC1 may have different electrical properties depending on whether it is doped or not. The first semiconductor pattern SC1 may include a first region having a relatively high conductivity and a second region having a relatively low conductivity. The first region may be doped with an N-type (kind) dopant or a P-type (kind) dopant. A P-type (kind) transistor may include a doped region doped with the P-type (kind) dopant, and an N-type (kind) transistor may include a doped region doped with the N-type (kind) dopant. The second region may be a non-doped region or a region doped at a concentration lower than that of the first region. In the present embodiment, the first semiconductor pattern SC1 may be the N-type (kind) transistor.

The first region may have a conductivity greater than that of the second region and may substantially serve as an electrode or signal line. The second region may substantially correspond to a channel area (or an active area) of a transistor. For example, a portion of the first semiconductor pattern SC1 may be a channel of the transistor, another portion of the first semiconductor pattern SC1 may be a source or a drain of the transistor, and the other portion of the first semiconductor pattern SC1 may be a connection electrode or a connection signal line.

A source area SE1, a channel area AC1 (or an active area), and a drain area DE1 of the silicon transistor S-TFT may be formed from the first semiconductor pattern SC1. The source area SE1 and the drain area DE1 may be extended in opposite directions to each other from the channel area AC1.

A first insulating layer 10 may be arranged on the buffer layer BFL. The first insulating layer 10 may cover the first semiconductor pattern SC1. The first insulating layer 10 may be an inorganic layer. The first insulating layer 10 may have a single-layer structure of a silicon oxide layer, however, it should not be limited thereto or thereby. An inorganic layer of the circuit layer DP-CL described in more detail later may have a single-layer or multi-layer structure, however, it should not be limited thereto or thereby.

A gate (or a gate electrode) GT1 of the silicon transistor S-TFT may be arranged on the first insulating layer 10. The gate GT1 may be a portion of a metal pattern. The gate GT1 may overlap the channel area AC1. The gate GT1 may be used as a mask in a process of doping the first semiconductor pattern SC1. A first electrode CE10 of the capacitor Cst may be arranged on the first insulating layer 10. Different from those shown in FIG. 6, the gate GT1 and the first electrode CE10 may be provided integrally with each other.

A second insulating layer 20 may be arranged on the first insulating layer 10 and may cover the gate GT1. An upper electrode may be further arranged on the second insulating layer 20 to overlap the gate GT1. A second electrode CE20 may be arranged on the second insulating layer 20 to overlap the first electrode CE10. The upper electrode may be provided integrally with the second electrode CE20 if (e.g., when) viewed in the plane.

A second shielding electrode BML2 may be arranged on the second insulating layer 20. The second shielding electrode BML2 may be arranged to correspond to the oxide transistor O-TFT. According to one or more embodiments, the second shielding electrode BML2 may not be provided. According to one or more embodiments, the first shielding electrode BML1 may be extended to a lower portion of the oxide transistor O-TFT and may replace the second shielding electrode BML2.

A third insulating layer 30 may be arranged on the second insulating layer 20. A second semiconductor pattern SC2 may be arranged on the third insulating layer 30. The second semiconductor pattern SC2 may include a channel area AC2 of the oxide transistor O-TFT. The second semiconductor pattern SC2 may include a metal oxide semiconductor. The second semiconductor pattern SC2 may include a transparent conductive oxide (TCO), such as indium tin oxide (ITO), indium zinc oxide (IZO), indium gallium zinc oxide (IGZO), zinc oxide (ZnOx), or indium oxide (In₂O₃).

The metal oxide semiconductor may include a plurality of areas SE2, AC2, and DE2 distinguished from each other depending on whether a transparent conductive oxide is reduced or not. The area (hereinafter, referred to as a reduced area) in which the transparent conductive oxide is reduced has a conductivity greater than that of the area (hereinafter, referred to as a non-reduced area) in which the transparent conductive oxide is not reduced. The reduced area may substantially act as a source/drain of a transistor or a signal line. The non-reduced area may substantially correspond to a semiconductor area (or a channel) of the transistor. For example, a portion of the second semiconductor pattern SC2 may be the semiconductor area of the transistor, another portion of the second semiconductor pattern SC2 may be a source area SE2/a drain area DE2 of the transistor, and the other portion of the second semiconductor pattern SC2 may be a signal transmission area.

A fourth insulating layer 40 may be arranged on the third insulating layer 30. As shown in FIG. 6, the fourth insulating layer 40 may cover the second semiconductor pattern SC2. According to one or more embodiments, the fourth insulating layer 40 may be an insulating pattern that overlaps a gate GT2 of the oxide transistor O-TFT and exposes the source area SE2 and the drain area DE2 of the oxide transistor O-TFT.

The gate GT2 of the oxide transistor O-TFT may be arranged on the fourth insulating layer 40. The gate GT2 of the oxide transistor O-TFT may be a portion of a metal pattern. The gate GT2 of the oxide transistor O-TFT may overlap the channel area AC2.

A fifth insulating layer 50 may be arranged on the fourth insulating layer 40 and may cover the gate GT2. Each of the first to fifth insulating layers 10 to 50 may be an inorganic layer.

A conductive layer may be arranged on the fifth insulating layer 50. The conductive layer may include a first connection pattern CNP1 and a second connection pattern CNP2. The first connection pattern CNP1 and the second connection pattern CNP2 may be formed through substantially the same process, and thus, the first connection pattern CNP1 and the second connection pattern CNP2 may include the same material and the same stack structure. The first connection pattern CNP1 may be connected to the drain area DE1 of the silicon transistor S-TFT via a first pixel contact hole PCH1 defined through the first, second, third, fourth, and fifth insulating layers 10, 20, 30, 40, and 50. The second connection pattern CNP2 may be connected to the source area SE2 of the oxide transistor O-TFT via a second pixel contact hole PCH2 defined through the fourth and fifth insulating layers 40 and 50. The connection relationship of the first connection pattern CNP1 and the second connection pattern CNP2 with respect to the silicon transistor S-TFT and the oxide transistor O-TFT should not be limited thereto or thereby.

A sixth insulating layer 60 may be arranged on the fifth insulating layer 50. A third connection pattern CNP3 may be arranged on the sixth insulating layer 60. The third connection pattern CNP3 may be connected to the first connection pattern CNP1 via a third pixel contact hole PCH3 defined through the sixth insulating layer 60. The data line DL may be arranged on the sixth insulating layer 60. A seventh insulating layer 70 may be arranged on the sixth insulating layer 60 and may cover the third connection pattern CNP3 and the data line DL. The third connection pattern CNP3 and the data line DL may be formed through substantially the same process, and thus, the third connection pattern CNP3 and the data line DL may include the same material and the same stack structure. Each of the sixth insulating layer 60 and the seventh insulating layer 70 may be an organic layer.

The first shielding electrode BML1, the gate GT1 of the silicon transistor S-TFT, the second electrode CE20, and the gate GT2 of the oxide transistor O-TFT may include molybdenum (Mo), an alloy including molybdenum (Mo), titanium (Ti), or an alloy including titanium (Ti), which has a good or suitable heat resistance. The first connection pattern CNP1 and the second connection pattern CNP2 may include aluminum with high electrical conductivity. The first connection pattern CNP1 and the second connection pattern CNP2 may have a three-layer structure of titanium/aluminum/titanium.

The light emitting element LD may include an anode (or a first electrode) AE, a light emitting layer EL, and a cathode (or a second electrode) CE. The anode AE of the light emitting element LD may be arranged on the seventh insulating layer 70. The anode AE may be a transmissive electrode, a semi-transmissive electrode, or a reflective electrode. The anode AE may have a stack structure of ITO/Ag/ITO that are sequentially stacked. Positions of the anode AE and the cathode CE may be interchanged.

A pixel definition layer PDL may be arranged on the seventh insulating layer 70. The pixel definition layer PDL may be an organic layer. The pixel definition layer PDL may have a light absorbing property and may have a black color. As an example, the pixel definition layer PDL may include a black coloring agent. The black coloring agent may include a black dye or a black pigment. The black coloring agent may include a metal material, such as carbon black, chromium, or an oxide thereof. The pixel definition layer PDL may correspond to a light blocking pattern having a light blocking property.

The pixel definition layer PDL may cover a portion of the anode AE. As an example, an opening PDL-OP may be defined through the pixel definition layer PDL to expose a portion of the anode AE. A light emitting area LA may be defined to correspond to the opening PDL-OP. In the present disclosure, a hole control layer may be arranged between the anode AE and the light emitting layer EL. The hole control layer may include a hole transport layer and may further include a hole injection layer. An electron control layer may be arranged between the light emitting layer EL and the cathode CE. The electron control layer may include an electron transport layer and may further include an electron injection layer.

The encapsulation layer TFE may cover the light emitting element LD. The encapsulation layer TFE may include a first encapsulation insulating layer IL1, a second encapsulation insulating layer IL2, and a third encapsulation insulating layer IL3. However, the present disclosure should not be limited thereto or thereby, and the encapsulation layer TFE may further include a plurality of inorganic layers and a plurality of organic layers.

The first encapsulation insulating layer IL1 may be an inorganic layer. The first encapsulation insulating layer IL1 may prevent or reduce external moisture or oxygen from entering the light emitting element LD. As an example, the first encapsulation insulating layer IL1 may include silicon nitride, silicon oxide, and/or a (e.g., any suitable) combination thereof. The first encapsulation insulating layer IL1 may be formed by a chemical vapor deposition process.

The second encapsulation insulating layer IL2 may be an organic layer. The second encapsulation insulating layer IL2 may be arranged on the first encapsulation insulating layer IL1 and may be in contact with the first encapsulation insulating layer IL1. The second encapsulation insulating layer IL2 may provide a flat surface on the first encapsulation insulating layer IL1. Uneven portions formed on an upper surface of the first encapsulation insulating layer IL1 or particles existing on the upper surface of the first encapsulation insulating layer IL1 may be covered by the second encapsulation insulating layer IL2, and thus, it is possible to block the influence of the surface condition of the upper surface of the first encapsulation insulating layer IL1 on the components formed on the second encapsulation insulating layer IL2. In addition, the second encapsulation insulating layer IL2 may relieve a stress between layers that are in contact with each other. The second encapsulation insulating layer IL2 may be formed through a solution process such as a spin coating process, a slit coating process, or an inkjet process.

The third encapsulation insulating layer IL3 may be arranged on the second encapsulation insulating layer IL2 and may cover the second encapsulation insulating layer IL2. The third encapsulation insulating layer IL3 may be formed stably on a relatively flat surface compared to being placed on the first encapsulation insulating layer IL1. The third encapsulation insulating layer IL3 may encapsulate moisture emitted from the second encapsulation insulating layer IL2 and may prevent or reduce moisture from leaking to outside.

The third encapsulation insulating layer IL3 may be optically transparent. The third encapsulation insulating layer IL3 may have a transmittance equal to or greater than about 90% in a visible wavelength range. The third encapsulation insulating layer IL3 may have a relatively higher light transmittance than that of the first encapsulation insulating layer IL1. The third encapsulation insulating layer IL3 may be an inorganic layer. The third encapsulation insulating layer IL3 may include silicon oxide (SiOx) or silicon oxynitride (SiON). The third encapsulation insulating layer IL3 may be formed through a chemical vapor deposition process. In one or more embodiments, each of the first encapsulation insulating layer IL1, the second encapsulation insulating layer IL2, and the third encapsulation insulating layer IL3 may include a plurality of layers, and it should not be particularly limited thereto.

The input sensing layer ISL may include at least one conductive layer (or at least one sensor conductive layer) and at least one insulating layer (or at least one sensor insulation layer). In the present embodiment, the input sensing layer ISL may include a first insulating layer IS-IL1, a first conductive layer ICL1, a second insulating layer IS-IL2, a second conductive layer ICL2, and a third insulating layer IS-IL3. FIG. 6 schematically shows a conductive line of the first conductive layer ICL1 and a conductive line of the second conductive layer ICL2.

The first insulating layer IS-IL1 may be arranged directly on the display panel DP. The first insulating layer IS-IL1 may be an inorganic layer including at least one of silicon nitride, silicon oxynitride, or silicon oxide. Each of the first conductive layer ICL1 and the second conductive layer ICL2 may have a single-layer structure or a multi-layer structure of layers stacked in the third direction DR3. The first conductive layer ICL1 and the second conductive layer ICL2 may include conductive lines that define an electrode of a mesh shape. The conductive line of the first conductive layer ICL1 and the conductive line of the second conductive layer ICL2 may be connected to each other via a contact hole defined through the second insulating layer IS-IL2 or may not be connected to each other. The connection relationship between the conductive line of the first conductive layer ICL1 and the conductive line of the second conductive layer ICL2 may be determined according to the type (kind) of sensor formed as the input sensing layer ISL.

The first conductive layer ICL1 and the second conductive layer ICL2, which have the single-layer structure, may include a metal layer or a transparent conductive layer. The metal layer may include molybdenum, silver, titanium, copper, aluminum, or alloys thereof. The transparent conductive layer may include a transparent conductive oxide, such as indium tin oxide (ITO), indium zinc oxide (IZO), zinc oxide (ZnOx), indium zinc tin oxide (ITZO), and/or the like. In addition, the transparent conductive layer may include conductive polymer such as PEDOT, metal nanowire, graphene, and/or the like.

The first conductive layer ICL1 and the second conductive layer ICL2, which have the multi-layer structure, may include metal layers. The metal layers may have a three-layer structure of titanium/aluminum/titanium. The first conductive layer ICL1 and the second conductive layer ICL2, which have the multi-layer structure, may include at least one metal layer and at least one transparent conductive layer. The second insulating layer IS-IL2 may be arranged between the first conductive layer ICL1 and the second conductive layer ICL2. The third insulating layer IS-IL3 may cover the second conductive layer ICL2. According to one or more embodiments, the third insulating layer IS-IL3 may not be provided. The second insulating layer IS-IL2 and the third insulating layer IS-IL3 may include an inorganic layer or an organic layer.

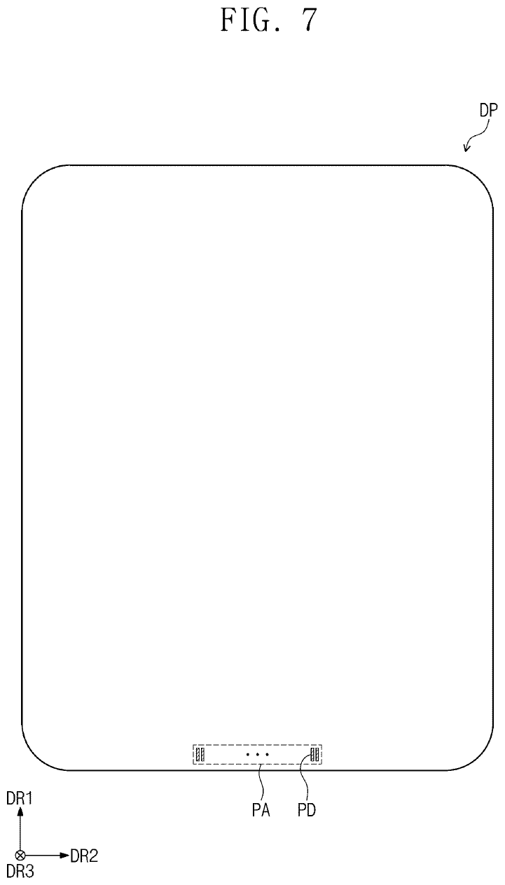

FIG. 7 is a plan view of the display panel DP according to one or more embodiments of the present disclosure. In more detail, FIG. 7 is a plan view of the display panel DP if (e.g., when) viewed in the third direction DR3.

Referring to FIG. 7, a pad electrode PD may be arranged on the rear surface of the display panel DP. In more detail, the pad electrode PD may be arranged in the pad area PA. The pad electrode PD may be provided in plural. The pad electrodes PD may be arranged in the second direction DR2.

The signal lines SGL (refer to FIG. 5) arranged in the display panel DP may be electrically connected to the circuit board FCB shown in FIG. 3 via the pad area PA. As an example, the signal lines SGL may be arranged in the pad area PA and may be connected to the pad electrodes PD, which are spaced and/or apart (e.g., spaced apart or separated) from the signal lines SGL in the first direction DR1, through the connection electrode. In one or more embodiments, the pad electrodes PD may be arranged on the rear surface of the display panel DP and may be electrically connected to the flexible circuit board FCB (refer to FIG. 2).

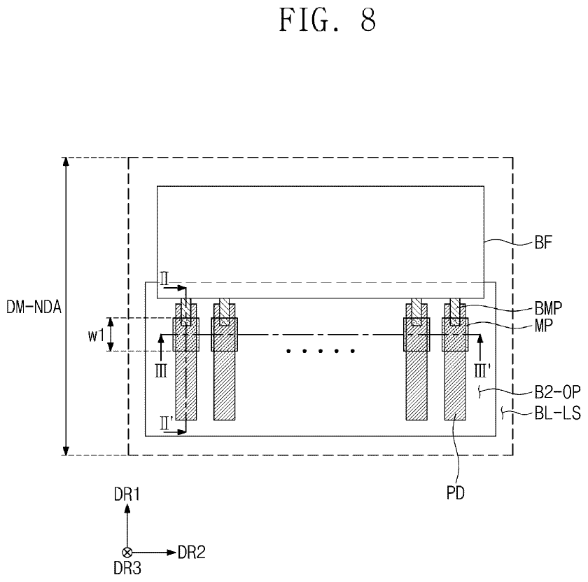

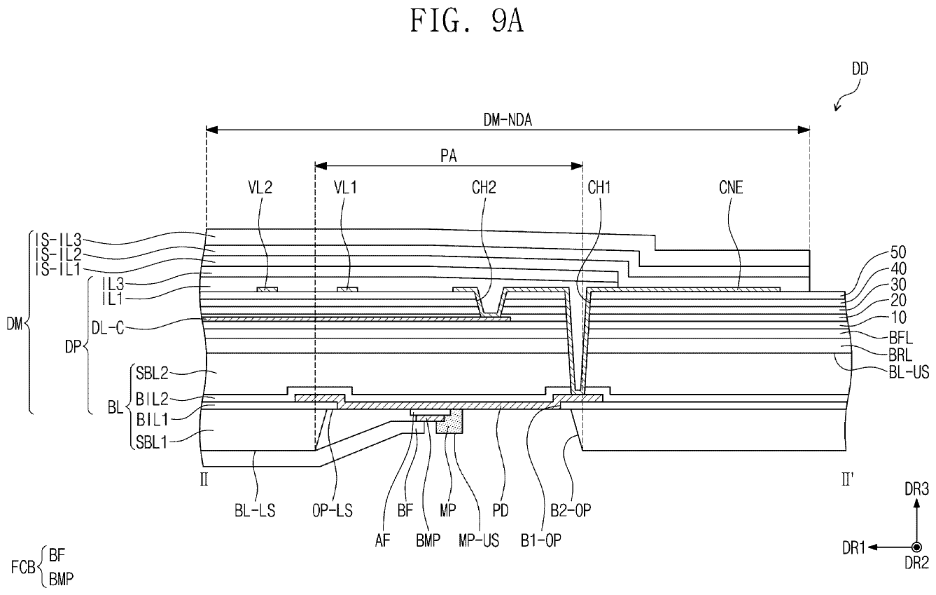

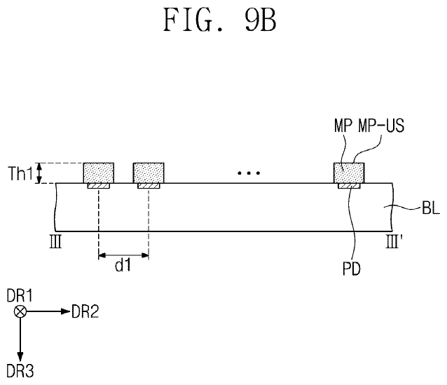

FIG. 8 is an enlarged plan view of a portion of the display device according to one or more embodiments of the present disclosure. FIG. 9A is a cross-sectional view of a portion of the display device DD taken along a line II-II′ of FIG. 8. FIG. 9B is a cross-sectional view of a portion of the display device DD taken along a line III-III′ of FIG. 8. FIGS. 8 and 9A show the structure in which the circuit board FCB is attached to the display panel DP.

Referring to FIGS. 8 and 9A, the display device DD may include a connection electrode CNE and the pad electrodes PD. The connection electrode CNE may be arranged on the same layer as the first connection pattern CNP1 shown in FIG. 6, and a portion of a data connection line DL-C, which overlaps the non-display area DM-NDA, may be arranged on the same layer as the gate GT1 of the silicon transistor S-TFT of FIG. 6. The data connection line DL-C may be electrically connected to the data line DL.

The pad electrodes PD may be exposed to the outside through a lower surface BL-LS of the base layer BL to be bonded to a rear surface of the circuit board FCB, however, the present disclosure should not be limited thereto or thereby. According to one or more embodiments, the pad electrodes PD may be exposed to the outside through a contact hole without being directly exposed. The lower surface BL-LS of the base layer BL may face an upper surface BL-US of the base layer BL in the third direction DR3.

The base layer BL may include a first sub-base layer SBL1, a first base insulating layer BIL1, a second base insulating layer BIL2, and a second sub-base layer SBL2, which are sequentially stacked. The first base insulating layer BIL1 may be arranged on the first sub-base layer SBL1, and the second base insulating layer BIL2 may be arranged on the first base insulating layer BIL1 and may cover the pad electrodes PD. The second sub-base layer SBL2 may be arranged on the second base insulating layer BIL2.

The first sub-base layer SBL1 and the second sub-base layer SBL2 may include a synthetic resin material, e.g., polyimide. The first base insulating layer BIL1 and the second base insulating layer BIL2 may include an inorganic material. As an example, the first base insulating layer BIL1 and the second base insulating layer BIL2 may include silicon nitride, silicon oxynitride, or silicon oxide.

The first base insulating layer BIL1 may be arranged on the first sub-base layer SBL1 and may be provided with a first opening B1-OP defined therethrough to expose a portion of the pad electrodes PD. The first sub-base layer SBL1 may be arranged under the first base insulating layer BIL1. The first sub-base layer SBL1 may provide the lower surface BL-LS of the base layer BL, and the first sub-base layer SBL1 may be provided with a second opening B2-OP defined therethrough to expose the pad electrodes PD to the outside of the display module DM. A portion of the first base insulating layer BIL1 may be exposed through the second opening B2-OP. The second opening B2-OP may have a size greater than a size of the first opening B1-OP.

The pad electrodes PD may be embedded in the base layer BL. However, the present disclosure should not be limited thereto or thereby, and the pad electrodes PD may be arranged on the lower surface BL-LS of the base layer BL. The base layer BL may have a single-layer structure of a synthetic resin layer or a multi-layer structure. Even though the base layer BL has the multi-layer structure, the first opening B1-OP and the second opening B2-OP may not be defined through the base layer. The pad electrodes PD arranged on the lower surface BL-LS of the base layer BL may be connected to the conductive pattern arranged on the upper surface BL-US of the base layer BL via contact holes defined through the base layer BL.

The connection electrode CNE may be connected to the pad electrodes PD via a first contact hole CH1 and may be connected to the data connection line DL-C via a second contact hole CH2. The first contact hole CH1 and the second contact hole CH2 may be arranged in the non-display area DM-NDA. The first contact hole CH1 may be penetrating through the insulating layers 10 to 50, the barrier layer BRL, the buffer layer BFL, and a portion of the base layer BL. The first contact hole CH1 may be penetrating through the second base insulating layer BIL2 and the second sub-base layer SBL2 of the base layer BL, and thus, the connection electrode CNE may be connected to the pad electrodes PD via the first contact hole CH1. The second contact hole CH2 may be penetrating through the second to fifth insulating layers 20 to 50. The connection electrode CNE may be connected to the data line DL via the second contact hole CH2.

The pad electrodes PD may be extended in the first direction DR1 and may be arranged in the second direction DR2, however, the shape and arrangement of the pad electrodes PD should not be limited thereto or thereby. The pad electrodes PD may overlap the non-display area DM-NDA. As an example, the pad electrodes PD may be arranged in the pad area PA.

The circuit board FCB may be attached to the display panel DP after being bent to the rear surface of the display panel DP. An adhesive layer AF may be arranged between the circuit board FCB and the lower surface BL-LS of the base layer BL. The circuit board FCB may be fixed to the lower surface BL-LS of the base layer BL by the adhesive layer AF.

The circuit board FCB may include a base film BF and a bump electrode BMP arranged on the base film BF. The base film BF may be formed as a single body and may be electrically connected to a plurality of bump electrodes BMP. In this case, the base film BF may include a plurality of lines therein, however, it should not be limited thereto or thereby. According to one or more embodiments, the base film BF may only be attached to the bump electrodes BMP and may not be electrically connected to the bump electrodes BMP. In this case, the base film BF may include a synthetic resin material, e.g., polyimide. The bump electrodes BMP may be arranged on the base film BF.

The bump electrodes BMP may overlap the pad electrodes PD if (e.g., when) viewed in the plane (e.g., in a plan view). The bump electrodes BMP may be electrically connected to the pad electrodes PD. The bump electrodes BMP may be formed to correspond to the pad electrodes PD. For example, one bump electrode BMP may correspond to one pad electrode PD. The bump electrodes BMP may be extended in the first direction DR1 and may be arranged in the second direction DR2. The pad electrodes PD may have a size greater than a size of the bump electrodes BMP if (e.g., when) viewed in the plane.

The adhesive layer AF may be arranged between the base film BF and the pad electrodes PD. According to one or more embodiments, the adhesive layer AF may include a non-conductive material. As an example, the adhesive layer AF may include a non-conductive film.

The bump electrodes BMP may be electrically connected to the pad electrodes PD. In more detail, the display device DD (refer to FIG. 2) may further include metal patterns MP that electrically connect the bump electrodes BMP and the pad electrodes PD. The metal patterns MP may be arranged on the pad electrodes PD and the bump electrodes BMP and may electrically connect the pad electrodes PD and the bump electrodes BMP. That is, the pad electrodes PD may be electrically connected to the bump electrodes BMP by the metal patterns MP. The metal patterns MP may be provided in numbers corresponding to each of the number of the pad electrodes PD and the number of the bump electrodes BMPI. For example, the display device DD (refer to FIG. 2) may include metal patterns MP that connect the bump electrodes BMP and the pad electrodes PD. These metal patterns MP may be arranged on both the pad electrodes PD and the bump electrodes BMP to establish an electrical connection. In other words, the pad electrodes PD are electrically connected to the bump electrodes BMP via the metal patterns MP. In the context of the present disclosure, “the number of metal patterns MP provided may correspond to the number of pad electrodes PD and bump electrodes BMP” refers to that the quantity of metal patterns (MP) created is equal to the number of pad electrodes PDa and bump electrodes (BMPa) that need to be connected. That is, for each pad electrode and bump electrode pair, there is a corresponding metal pattern to establish the electrical connection between them. For example, if there are 10 pad electrodes and 10 bump electrodes, there will be 10 metal patterns to connect each pair. Each of the metal patterns MP may be obtained by curing a metal ink. The metal patterns MP may include a solder paste. The metal patterns MP may be formed of the metal ink containing silver or copper. The metal patterns MP may be arranged to correspond to the pad electrodes PD exposed through the second opening B2-OP. The metal patterns MP may be formed by curing the metal ink and patterning the cured metal ink. The metal patterns MP may be formed at a low temperature and may bond and electrically connect the pad electrodes PD and the bump electrodes BMP together without a pressing process at a high temperature. Processes of forming the metal patterns MP will be described in more detail later. The metal patterns MP may have a width w1 equal to or greater than about 80 μm and equal to or smaller than about 120 μm in the first direction DR1.

Referring to FIGS. 9A and 9B, each of the metal patterns MP may include a flat upper surface MP-US. The upper surface MP-US may be substantially parallel to a lower surface OP-LS (or an upper surface of the pad electrodes) of the second opening B2-OP. The metal patterns MP may be formed by patterning a metal layer having a substantially non-uniform thickness. Accordingly, the second base insulating layer BIL2 (or a substrate) may be patterned if (e.g., when) portions of the metal layer, which have a relatively thin thickness, are patterned, and thus, the second base insulating layer BIL2 may be damaged. According to the present disclosure, because the metal patterns MP may be formed by patterning a metal layer having a substantially uniform thickness, the second base insulating layer BIL2 may be prevented or reduced from being damaged during the processes of forming the metal patterns MP. FIG. 9B shows a structure in which the pad electrodes PD are embedded in the base layer BL, however, the base layer BL shown in FIG. 9B may correspond to the second base insulating layer BIL2 shown in FIG. 9A.

Each of the metal patterns MP may have a first thickness Th1 in the third direction DR3. The metal patterns MP may have a quadrangular shape if (e.g., when) viewed in cross-section. The first thickness Th1 of the metal patterns MP may be substantially uniform in the second direction DR2. In one or more embodiments, the first thickness Th1 of the metal patterns MP may also be substantially uniform in the first direction DR1. The first thickness Th1 may be equal to or greater than about 10 μm and equal to or smaller than about 20 μm.

According to one or more embodiments of the present disclosure, a pitch d1 between the pad electrodes PD adjacent to each other may be equal to or greater than about 10 μm and equal to or smaller than about 30 μm. That is, a pitch d1 between a pad electrode PD and an adjacent pad electrode PD may be equal to or greater than about 10 μm and equal to or smaller than about 30 μm. As an example, the pitch d1 between the pad electrodes PD adjacent to each other may be about 20 μm. Pitches d1 between the pad electrodes PD adjacent to each other may be the same as each other. However, the present disclosure should not be limited thereto or thereby, and the pitches d1 between the pad electrodes PD adjacent to each other may be different from each other. A pitch between the metal patterns MP adjacent to each other may be the same as the pitch d1 between the pad electrodes PD adjacent to each other.

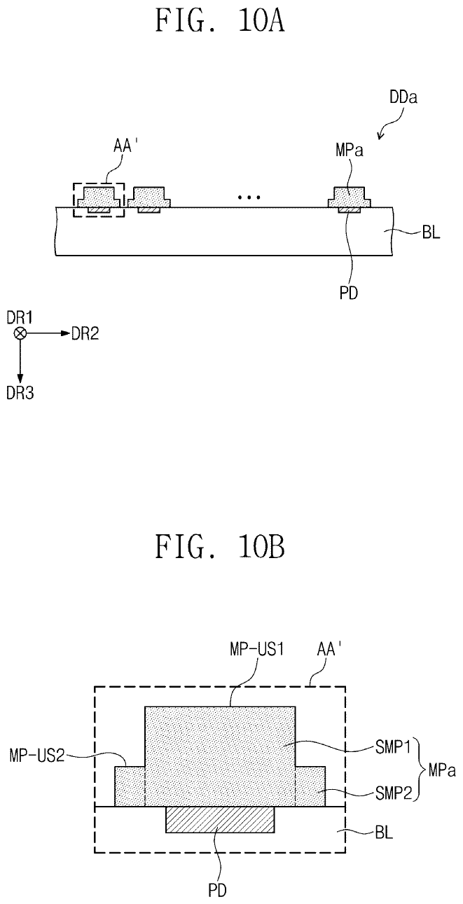

FIG. 10A is a cross-sectional view of a portion of a display device DDa according to one or more embodiments of the present disclosure. FIG. 10B is an enlarged view of an area AA′ of FIG. 10A.

Referring to FIGS. 10A and 10B, each of metal patterns MPa may include a first sub-metal pattern SMP1 and a second sub-metal pattern SMP2. The second sub-metal pattern SMP2 may be extended from the first sub-metal pattern SMP1. According to one or more embodiments, the first sub-metal pattern SMP1 and the second sub-metal pattern SMP2 may have different thicknesses from each other. The thickness of the first sub-metal pattern SMP1 may be greater than the thickness of the second sub-metal pattern SMP2.

The first sub-metal pattern SMP1 may include a first upper surface MP-US1, and the second sub-metal pattern SMP2 may include a second upper surface MP-US2. The first upper surface MP-US1 and the second upper surface MP-US2 may be substantially parallel to each other. As shown in FIG. 10B, each of the thickness of the first sub-metal pattern SMP1 and the thickness of the second sub-metal pattern SMP2 may be substantially uniform in the second direction DR2. In one or more embodiments, each of the thickness of the first sub-metal pattern SMP1 and the thickness of the second sub-metal pattern SMP2 may be substantially uniform in the first direction DR1.

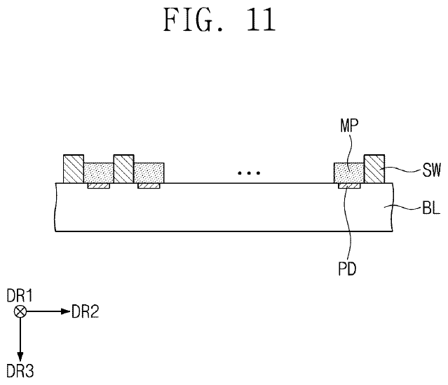

FIG. 11 is a cross-sectional view of a portion of a display device according to one or more embodiments of the present disclosure.

Referring to FIG. 11, barrier walls SW may be arranged between metal patterns MP adjacent to each other in the second direction DR2. A side surface of the barrier walls SW may be in contact with a side surface of the metal patterns MP. The barrier walls SW may have a thickness greater than the thickness of the metal patterns MP. The barrier walls SW may include an optical clear resin, however, materials for the barrier walls SW should not be limited thereto or thereby. According to one or more embodiments, the barrier walls SW may include a suitable adhesive. As an example, the barrier walls SW may include a pressure sensitive adhesive (PSA) or an optical clear adhesive (OCA). The metal patterns MP may be formed between the barrier walls SW adjacent to each other after the barrier walls SW are formed.

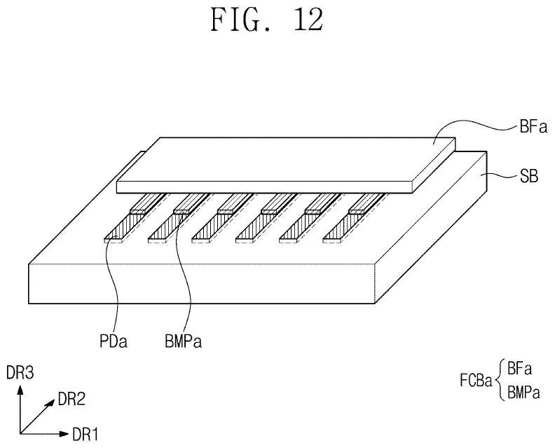

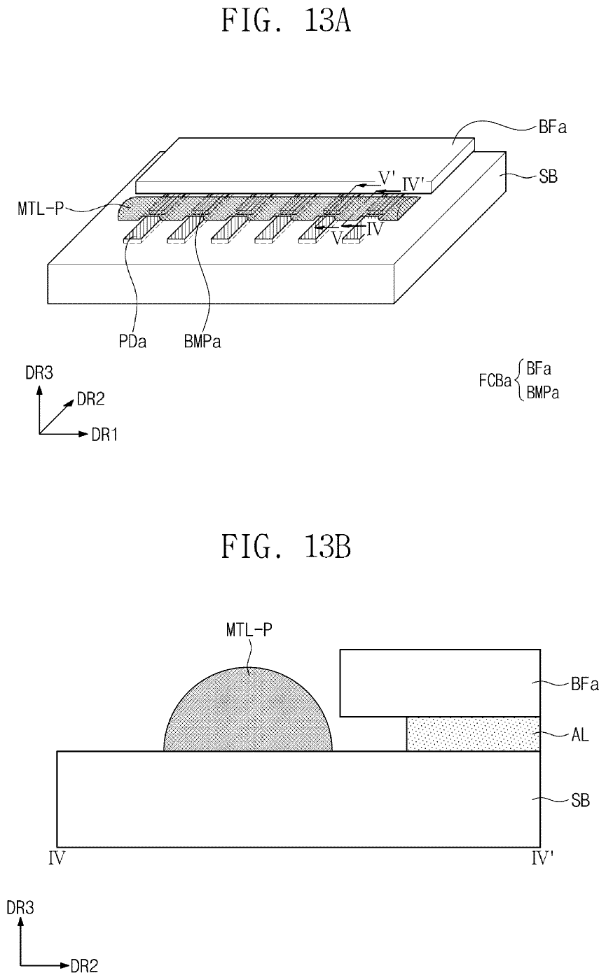

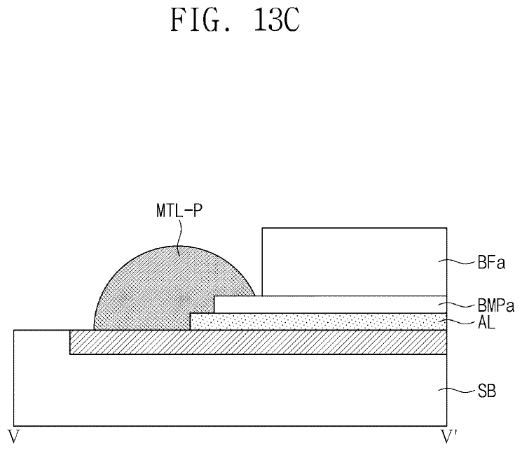

FIGS. 12 to 17 are views illustrating processes of a manufacturing method of the display device according to one or more embodiments of the present disclosure.

Referring to FIG. 12, a process of placing a circuit board FCBa on a substrate SB in which pad electrodes PDa are embedded is performed. The circuit board FCBa may include a base film BFa and a bump electrode BMPa. The substrate SB, the pad electrodes PDa, and the circuit board FCBa shown in FIG. 12 may correspond to the base layer BL, the pad electrodes PD, and the circuit board FCB shown in FIG. 9A, and thus, detailed descriptions thereof will not be provided. The bump electrode BMPa may be arranged to overlap the pad electrodes PDa if (e.g., when) viewed in the plane. The pad electrodes PDa may be exposed to the outside through the second opening (refer to B2-OP of FIG. 9A).

Referring to FIGS. 13A to 13C, a preliminary metal layer MTL-P may be arranged on the pad electrodes PDa and the bump electrode BMPa. The preliminary metal layer MTL-P may be arranged on the pad electrodes PDa and the bump electrode BMPa as a single unitary body. The preliminary metal layer MTL-P may have a substantially non-uniform thickness. As an example, the preliminary metal layer MTL-P may have the substantially non-uniform thickness in the second direction DR2.

Referring to FIGS. 13B and 13C, an adhesive layer AL may be arranged between the substrate SB and the base film BFa. The substrate SB may be attached to the base film BFa by the adhesive layer AL. The adhesive layer AL may include a non-conductive material. As an example, the adhesive layer AL may be provided in the form of a non-conductive film between the substrate SB and the base film BFa. According to one or more embodiments, the adhesive layer AL may not be provided. The preliminary metal layer MTL-P may have a hemisphere shape if (e.g., when) viewed in a cross-section (e.g., in a cross-sectional view). The pad electrodes PDa may be electrically connected to the bump electrode BMPa by the preliminary metal layer MTL-P.

The preliminary metal layer MTL-P may include a first portion that overlaps the pad electrodes PDa and the bump electrode BMPa and a second portion that does not overlap the pad electrodes PDa and the bump electrode BMPa. The preliminary metal layer MTL-P shown in FIG. 13B may correspond to the second portion, and the preliminary metal layer MTL-P shown in FIG. 13C may correspond to the first portion.

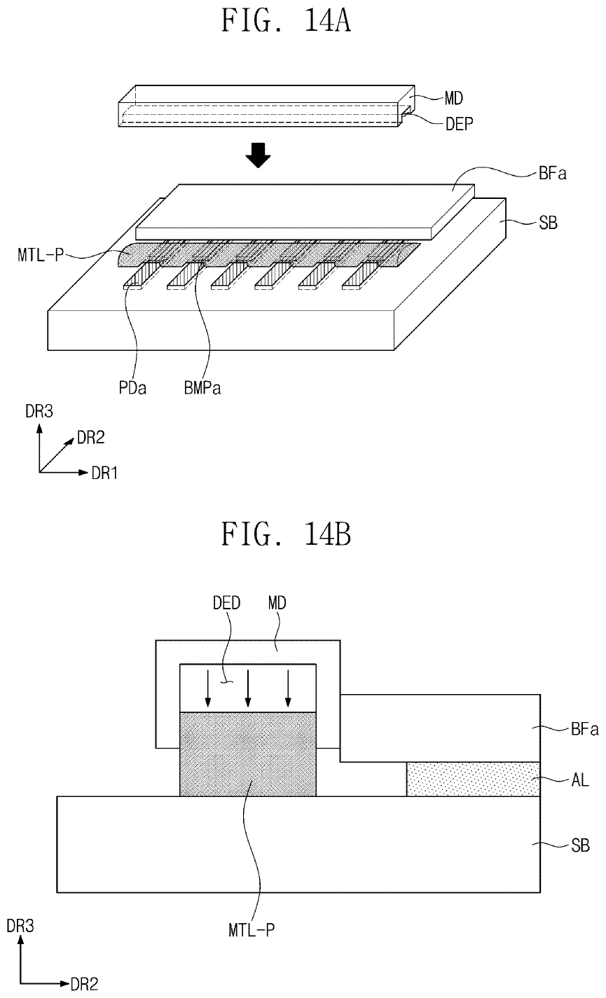

Referring to FIG. 14A, a mold MD may be arranged on the preliminary metal layer MTL-P. The mold MD may include a transparent material. As an example, the mold MD may include a material that is configured to transmit a light. In more detail, the mold MD may be configured to transmit a light within a wavelength range equal to or greater than about 350 nm and equal to or smaller than about 450 nm.

The mold MD may include a depressed portion DEP. The depressed portion DEP may be formed by recessing a lower portion of the mold MD. The depressed portion DEP may have a quadrangular shape in a cross-section if (e.g., when) viewed in the first direction DR1. The depressed portion DEP may be extended in the first direction DR1 in substantially the same way as the preliminary metal layer MTL-P.

Referring to FIGS. 14A and 14B, a process of pressing the preliminary metal layer MTL-P may be performed. In more detail, the preliminary metal layer MTL-P may be pressed by using the mold MD, and the preliminary metal layer MTL-P may be arranged in the depressed portion DEP of the mold MD. As a result, the shape in the cross-section of the preliminary metal layer MTL-P if (e.g., when) viewed in the first direction DR1 may be substantially the same as the shape in the cross-section of the depressed portion DEP if (e.g., when) viewed in the first direction DR1. The shape in the cross-section of the preliminary metal layer MTL-P if (e.g., when) viewed in the first direction DR1 may be the quadrangular shape. The preliminary metal layer MTL-P may include a flat upper surface. The upper surface of the preliminary metal layer MTL-P shown in FIG. 14B may correspond to the second portion shown in FIG. 13B. The preliminary metal layer MTL-P may have a substantially uniform thickness in the second direction DR2.

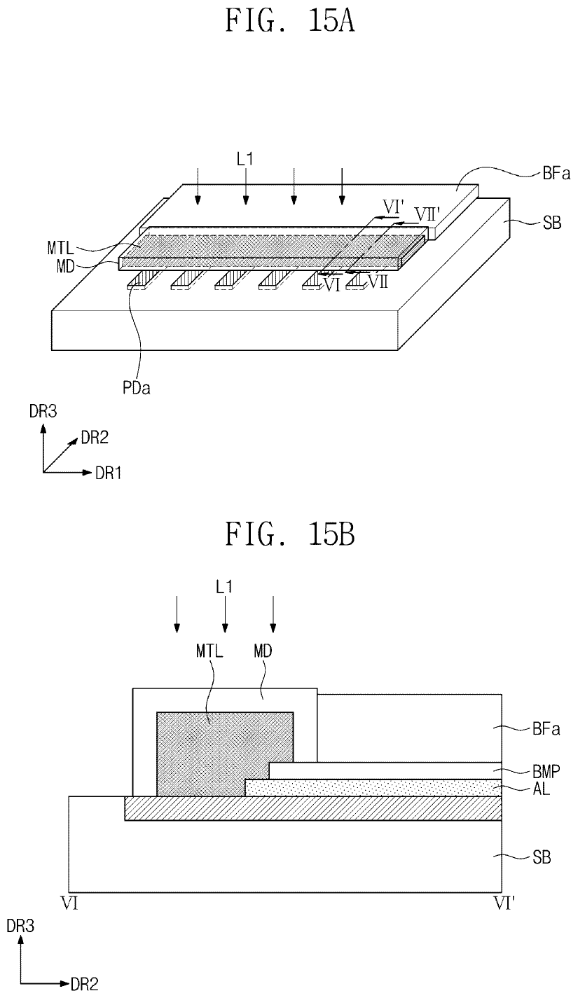

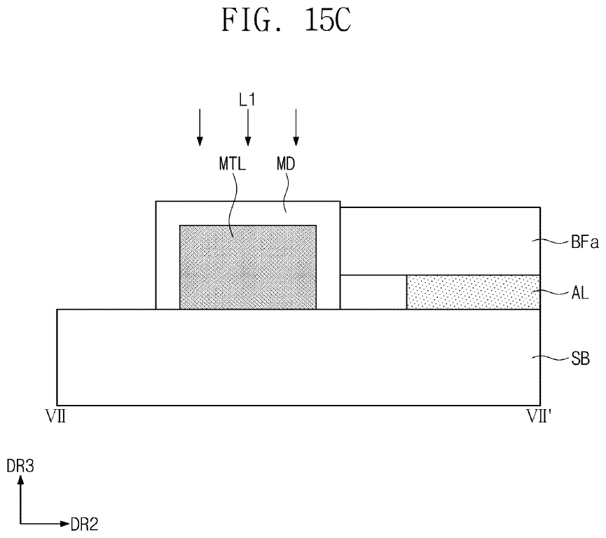

Referring to FIGS. 15A to 15C, a process of curing the preliminary metal layer MTL-P (refer to FIG. 14A) may be performed to form the metal layer MTL. The process of curing the preliminary metal layer MTL-P (refer to FIG. 14A) may include a process of irradiating a light L1 onto the mold MD. The light L1 may have a wavelength equal to or greater than about 350 nm and equal to or smaller than about 450 nm. For example, because the mold MD is configured to transmit the light having the wavelength equal to or greater than about 350 nm and equal to or smaller than about 450 nm, the light L1 may be irradiated onto the preliminary metal layer MTL-P without being affected by the mold MD, and thus, the preliminary metal layer MTL-P may be cured.

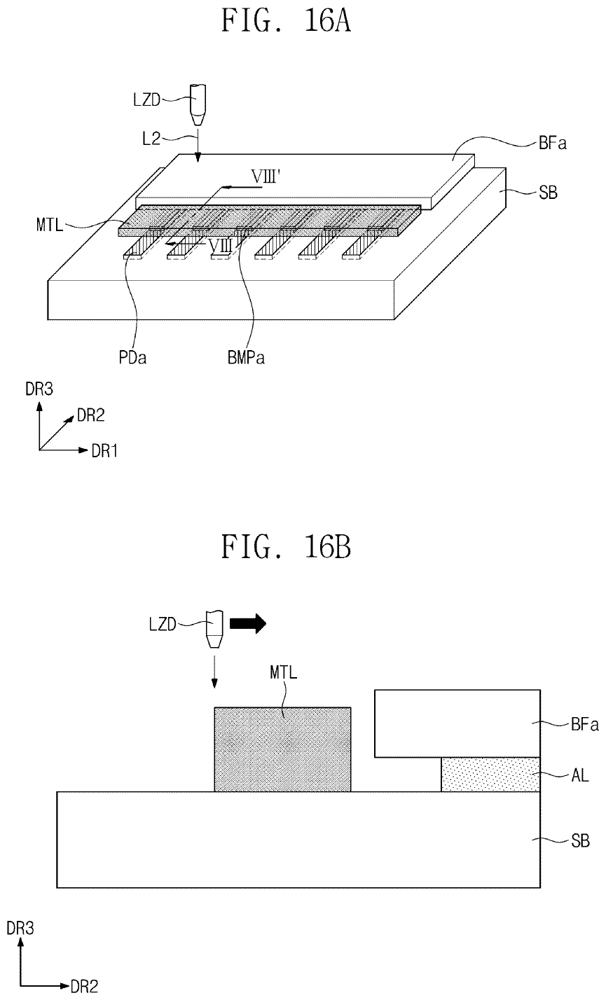

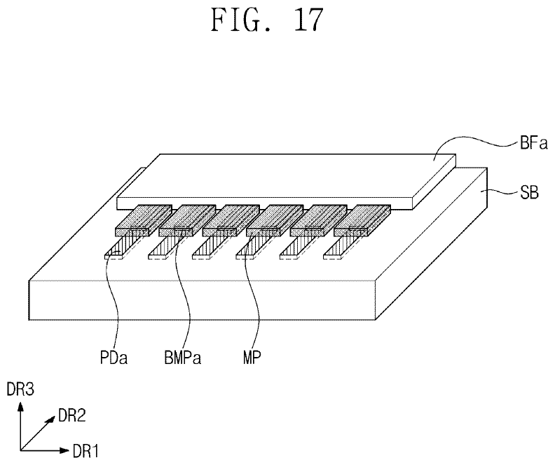

Referring to FIGS. 16A and 16B, a process of irradiating a laser L2 onto the metal layer MTL is performed. In more detail, a laser irradiation device LZD may be arranged above the metal layer MTL, and the laser L2 may be irradiated to the metal layer MTL arranged in an area that does not overlap the pad electrodes PDa and the bump electrode BMPa by the laser irradiation device LZD. Referring to FIGS. 16A, 16B, and 17, the metal layer MTL may be patterned by the laser L2, and the metal patterns MP may be formed. The metal patterns MP may correspond to the metal patterns MP shown in FIG. 9A. The metal patterns MP may electrically connect the pad electrodes PDa and the bump electrodes BMPa. That is, the pad electrodes PDa may be electrically connected to the bump electrodes BMPa by the metal patterns MP. The metal patterns MP may be provided in numbers corresponding to each of the number of the pad electrodes PDa and the number of the bump electrodes BMPa. For example, the metal patterns MP may be arranged on both the pad electrodes PDa and the bump electrodes BMPa to establish an electrical connection. In other words, the pad electrodes PDa are electrically connected to the bump electrodes BMPa via the metal patterns MP. In the context of the present disclosure, “the number of metal patterns MP provided may correspond to the number of pad electrodes PDa and bump electrodes BMPa” refers to that the quantity of metal patterns (MP) created is equal to the number of pad electrodes PDa and bump electrodes (BMPa) that need to be connected. That is, for each pad electrode and bump electrode pair, there is a corresponding metal pattern to establish the electrical connection between them. For example, if there are 10 pad electrodes and 10 bump electrodes, there will be 10 metal patterns to connect each pair.

Referring to FIGS. 12 to 17, if (e.g., when) the metal layer having a substantially non-uniform thickness, e.g. the preliminary metal layer MTL-P shown in FIG. 13A, is patterned by the laser L2, the substrate SB may also be patterned by the laser L2 during a process of patterning the metal layer having a relatively thin thickness, and the substrate SB may be damaged. Because the manufacturing method of the display device DD (refer to FIG. 2) includes the pressing of the preliminary metal layer MTL-P having the substantially non-uniform thickness using the mold MD, the laser L2 may be irradiated onto the preliminary metal layer MTL-P having the flat upper surface, and thus, the substrate SB may be prevented or reduced from being damaged while patterning the metal layer MTL. Accordingly, the reliability of the display device DD may be improved.

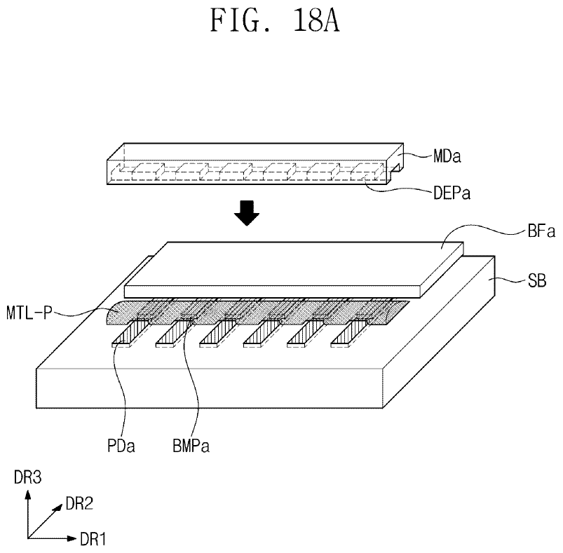

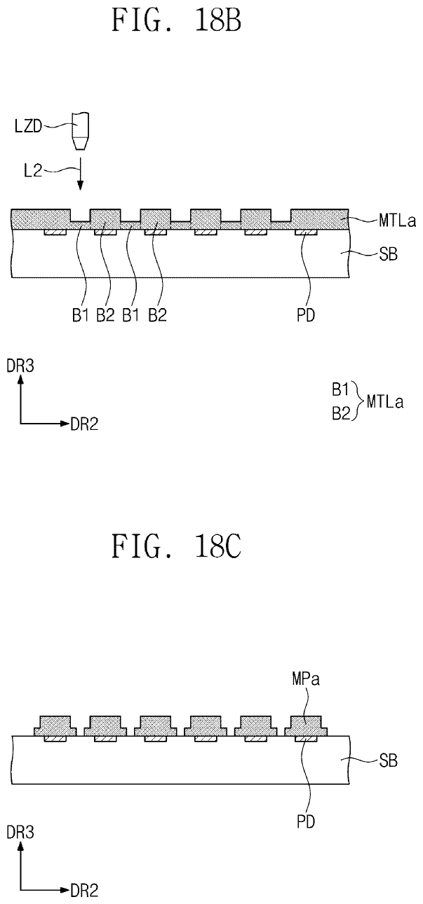

FIGS. 18A to 18C are views illustrating processes of a manufacturing method of the display device according to one or more embodiments of the present disclosure. In more detail, some of the processes of manufacturing the display device DDa of FIG. 10A are shown.

Referring to FIG. 18A, a mold MDa may be arranged on a preliminary metal layer MTL-P. The mold MDa may include a depressed portion DEPa. The depressed portion DEPa may have a quadrangular shape in cross-section if (e.g., when) viewed in the first direction DR1. The depressed portion DEPa may be provided in plural. The depressed portions DEPa may be arranged in the first direction DR1.

Referring to FIGS. 18A and 18B, the preliminary metal layer MTL-P may be pressed by using the mold MDa, and a metal layer MTLa including a first portion B1 and a second portion B2 having a thickness different from that of the first portion B1 may be formed. The thickness of the first portion B1 may be smaller than the thickness of the second portion B2. The second portion B2 may overlap the depressed portions DEPa. A laser L2 may be irradiated to the first portion B1.

Therefore, the laser L2 may be irradiated to the first portion B1 that does not overlap pad electrodes PDa and bump electrode BMPa. Referring to FIGS. 18A to 18C, the metal layer MTLa may be patterned by the laser L2 to form the metal patterns MPa. The metal patterns MPa may correspond to the metal patterns MPa shown in FIG. 10A.

Referring to FIGS. 18A to 18C, the laser L2 may be irradiated to the first portion B1 that is thinner than the second portion B2 to form the metal patterns MPa. In this case, an output of the laser L2 to form the metal patterns MPa may be reduced, and as a result, a possibility of damaging the substrate SB may be reduced.

The display device, the electronic apparatus, the electronic equipment or device, a manufacturing device for the display device, the electronic apparatus, the electronic equipment or device or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the present disclosure have been described, it is understood that the present disclosure should not be limited to these embodiments but one or more suitable changes and modifications can be made by one ordinary skilled in the art within the spirit and scope of the present disclosure as hereinafter claimed.

Therefore, the disclosed subject matter should not be limited to any single embodiment described herein, and the scope of the present disclosure shall be determined according to the attached claims.

What is claimed is:

1. A display device comprising:
a display panel configured to display an image;
a circuit board coupled with the display panel; and
a plurality of metal patterns electrically connecting the display panel and the circuit board and comprising a flat upper surface,
the display panel comprising:
a base layer comprising a pad electrode exposed to an outside through an opening; and
a circuit layer on the base layer and comprising at least one signal line electrically connected to the pad electrode,
wherein the flat upper surface is substantially parallel to an upper surface of the pad electrode.

2. The display device of claim 1, wherein each of the metal patterns comprises:
a first sub-metal pattern; and
a second sub-metal pattern being extended from the first sub-metal pattern, and the first sub-metal pattern has a thickness greater than a thickness of the second sub-metal pattern.

3. The display device of claim 2, wherein the first sub-metal pattern comprises a first upper surface substantially parallel to a second upper surface of the second sub-metal pattern.

4. The display device of claim 1, wherein the circuit board comprises:
a base film; and
a bump electrode between the base film and the base layer, and
wherein the bump electrode is electrically connected to the pad electrode via the metal patterns.

5. A method comprising:
providing a plurality of pad electrodes exposed through an opening defined through a base layer and arranged in a first direction and providing a plurality of bump electrodes on the pad electrodes overlapping the pad electrodes, respectively, in a plan view;
placing a preliminary metal layer having a substantially non-uniform thickness in a second direction intersecting the first direction on the pad electrodes and the bump electrodes;
placing a mold on the preliminary metal layer to form a metal layer with a flat upper surface; and
irradiating a laser to a first portion of the metal layer, the first portion of the metal layer not overlapping the pad electrodes and the bump electrodes, to form a plurality of metal patterns,
wherein the pad electrodes are electrically connected to the bump electrodes via the metal patterns, and
wherein the method is a method of manufacturing a display device.

6. The method of claim 5, wherein the forming of the metal layer comprises:
pressing the preliminary metal layer utilizing the mold; and
curing the preliminary metal layer.

7. The method of claim 6, wherein the curing of the preliminary metal layer comprises irradiating a light to the mold.

8. The method of claim 7, wherein the mold is configured to transmit a light having a wavelength equal to or greater than about 350 nm and equal to or smaller than about 450 nm.

9. The method of claim 5, wherein the mold comprises a depressed portion defined therein, and the depressed portion has a quadrangular shape in a cross-section when viewed in the first direction.

10. The method of claim 9, wherein the metal layer and the depressed portion are extended in the first direction.

11. The method of claim 9, wherein a shape in the cross-section of the first portion when viewed in the first direction is equal to a shape in the cross-section of the depressed portion when viewed in the first direction, and the first portion has substantially uniform thickness in the second direction.

12. The method of claim 9, wherein the depressed portion is provided in plural, and the depressed portions are arranged in the first direction.

13. The method of claim 12, wherein the first portion has a thickness smaller than a thickness of a second portion of the metal layer, the second portion of the metal layer overlapping the pad electrodes and the bump electrodes.

14. The method of claim 13, wherein the second portion of the metal layer overlaps the depressed portions.

15. The method of claim 13, wherein each of the metal patterns comprises a first sub-metal pattern and a second sub-metal pattern being extended from the first sub-metal pattern, and the first sub-metal pattern and the second sub-metal pattern have different thicknesses from each other.

16. The method of claim 15, wherein the second sub-metal pattern corresponds to a portion of the first portion, which remains after the other portion of the first portion is removed by the laser, the first sub-metal pattern corresponds to the second portion, and the first sub-metal pattern has a thickness greater than a thickness of the second sub-metal pattern.

17. The method of claim 16, wherein the first sub-metal pattern comprises a first upper surface that is substantially parallel to a second upper surface of the second sub-metal pattern.

18. The method of claim 5, further comprising removing the mold before the forming of the metal patterns.

19. The method of claim 5, further comprising placing an adhesive layer on the pad electrodes before the providing of the bump electrodes.

20. An electronic device comprising:
a display device comprising:
a display panel configured to display an image;
a circuit board coupled with the display panel; and
a plurality of metal patterns electrically connecting the display panel and the circuit board and comprising a flat upper surface,
the display panel comprising:
a base layer comprising a pad electrode exposed to an outside through an opening; and
a circuit layer on the base layer and comprising at least one signal line electrically connected to the pad electrode,
wherein the flat upper surface is substantially parallel to an upper surface of the pad electrode.
